(19) United States
(12) Patent Application Publication
(10) Pub. No.: US 2026/0282568 A1
(43) Pub. Date: Sep. 17, 2026

(54) SENSOR, METHOD FOR MANUFACTURING A SENSOR, ELECTRONIC DEVICE AND METHOD FOR OPERATING A SENSOR

(71) Applicant: ams-OSRAM International GmbH, Regensburg (DE)

(72) Inventor: Daniel Richter, Bad Abbach (DE)

(21) Appl. No.: 19/474,337

(22) PCT Filed: Apr. 30, 2024
(86) PCT No.: PCT/EP2024/061939

§ 371 Date: Oct. 10, 2025

(30) Foreign Application Priority Data
May 8, 2023 (DE) 10 2023 111 971.0

(51) Int. Cl. H10F 39/10; H10F 77/30

(52) U.S. Cl. CPC H10F 39/107; H10F 77/331

(57) ABSTRACT

In an embodiment a sensor includes individually readable detector elements and filter elements arranged above the detector elements, respectively, wherein each filter element includes a first compound semiconductor material having a composition ratio changing along a vertical direction, wherein the first compound semiconductor material is a III-V semiconductor material, which includes elements of group III and at least one element of group V, wherein a proportion of the elements of group III changes along the vertical direction and a proportion of the at least one element of group V remains greater than zero, and wherein at least two filter elements have layer thicknesses of the first compound semiconductor material that are different from one another.

### CROSS-REFERENCE TO RELATED APPLICATIONS

This patent application is a national phase filing under section 371 of PCT/EP2024/061939, filed Apr. 30, 2024, which claims the priority of German patent application no. 102023111971.0, filed May 8, 2023, each of which is incorporated herein by reference in its entirety.

### TECHNICAL FIELD

The present disclosure relates to a sensor, in particular a multispectral sensor, which is suitable for detecting incident electromagnetic radiation in different wavelength ranges.

### BACKGROUND

Sensors, for example sensors for detecting UV radiation, are based on semiconductor diodes which are suitable for converting incident electromagnetic radiation into a photocurrent. In general, concepts are sought with which detected radiation can be resolved and quantified according to its wavelength.

### SUMMARY

Embodiments provide an improved sensor and an improved method for manufacturing a sensor.

According to embodiments, a sensor comprises an arrangement of sensor elements. The sensor elements comprise an individually readable detector element and a filter element arranged above the detector element, respectively. The filter element contains a first compound semiconductor material having a composition ratio changing along a vertical direction. The first compound semiconductor material is a III-V semiconductor material which contains elements of group III and at least one element of group V, and the proportion of the elements of group III changes along the vertical direction. In this case, the proportion of the at least one element of group V remains greater than zero. At least two filter elements have layer thicknesses of the first compound semiconductor material that are different from one another. For example, the filter element consists of the first compound semiconductor material. For example, the compound semiconductor material can be AlₓGa₁₋ₓAs, wherein x changes along the vertical direction. The feature that the proportion of the at least one element of group V remains greater than zero can mean that the element of group V does not change along the vertical direction. For example, a case can be excluded in which a part of the filter element contains an As compound semiconductor and another part of the filter element contains a P or N compound semiconductor.

According to embodiments, the sensor further comprises a cover element arranged between two adjacent filter elements. For example, the cover element can cover a part of a surface of the filter elements.

According to embodiments, the sensor further comprises a filter layer over the filter elements.

For example, the composition ratio of the first compound semiconductor material can change continuously. According to further embodiments, the composition ratio can change stepwise.

According to embodiments, the detector element can be formed in a second compound semiconductor material. At least one composition element of the second compound semiconductor material can be a component of the first compound semiconductor material.

According to further embodiments, the detector element can be formed in a semiconductor material different from the first compound semiconductor material.

For example, at least two detector elements can be identical to one another.

According to embodiments, a band gap of the first compound semiconductor material can decrease with increasing distance from a surface of the associated detector element.

According to embodiments, the first compound semiconductor material layer can additionally contain impurities, lattice voids, lattice defects or a semiconductor material having an indirect band gap.

According to embodiments, the sensor can also further comprise a transparent, insulating passivation layer over the first compound semiconductor layer, wherein the passivation layer contains impurities, lattice voids, lattice defects or a semiconductor material having an indirect band gap.

Further embodiments relate to a method for manufacturing a sensor comprising an arrangement of sensor elements, which comprise an individually readable detector element and a filter element arranged above an associated detector element, respectively. The method comprises forming a plurality of filter elements, which contain a first compound semiconductor material having a composition ratio changing along a vertical direction, respectively. The first compound semiconductor material is a III-V semiconductor material which contains elements of group III and at least one element of group V, and the proportion of the elements of group III changes along the vertical direction and the proportion of the at least one element of group V remains greater than zero. The method further comprises partially removing the first compound semiconductor material of at least one filter element, so that layer thicknesses of the first compound semiconductor material that are different from one another are achieved over at least two detector elements.

For example, forming the plurality of filter elements can comprise applying the first compound semiconductor material over the arrangement of sensor elements. Subsequently, the first compound semiconductor material can be partially removed after applying the first compound semiconductor material.

According to embodiments, the filter elements can be applied over the detector elements after partially removing the first compound semiconductor material.

Further embodiments relate to an electronic device comprising the sensor as defined above.

The electronic device can be selected from an exploration satellite or an analysis device.

Further embodiments relate to a method for operating a sensor as defined above. The method comprises reading out detector signals of at least two sensor elements, which have different layer thicknesses of the filter element, respectively, and determining a spectral signal from the difference of the detector signals.

### BRIEF DESCRIPTION OF THE DRAWINGS

The accompanying drawings serve to understand embodiments of the invention. The drawings illustrate embodiments and together with the description serve to explain them. Further embodiments and numerous of the intended advantages emerge directly from the following detailed description. The elements and structures shown in the drawings are not necessarily illustrated true to scale with respect to one another. Identical reference signs refer to identical or mutually corresponding elements and structures.

FIG. 1A shows a schematic cross-sectional view of a sensor according to embodiments;

FIG. 1B shows a view of a front side of a sensor according to embodiments;

FIG. 1C shows a view of a rear side of a sensor according to embodiments;

FIG. 1D illustrates the principle for spectral resolution of the detected electromagnetic radiation;

FIG. 2A shows a cross-sectional view of a sensor according to further embodiments;

FIG. 2B shows a cross-sectional view of a sensor according to further embodiments;

FIG. 2C shows a cross-sectional view of a sensor according to further embodiments;

FIGS. 3A to 3C illustrate a method for manufacturing a sensor according to embodiments;

FIGS. 4A and 4B illustrate a method for manufacturing a sensor according to further embodiments;

FIG. 5A shows an example of a sensor comprising a control circuit;

FIG. 5B summarizes a method for manufacturing a sensor;

FIG. 5C illustrates an electronic device according to embodiments; and

FIG. 5D summarizes a method for operating a sensor.

### DETAILED DESCRIPTION OF ILLUSTRATIVE EMBODIMENTS

In the following detailed description, reference is made to the accompanying drawings, which form part of the disclosure and in which specific embodiments are shown for illustrative purposes. In this context, directional terminology such as “top”, “bottom”, “front”, “back”, “over”, “on”, “in front”, “behind”, “front”, “rear”, etc. is referred to the orientation of the figures being described. Since the components of the embodiments can be positioned in different orientations, the directional terminology serves only for explanation and is in no way restrictive.

The description of the embodiments is not restrictive since other embodiments also exist and structural or logical changes can be made without deviating from the scope defined by the patent claims. In particular, elements of embodiments described below can be combined with elements of other embodiments described unless the context indicates otherwise.

The terms “wafer” or “semiconductor substrate” used in the following description can comprise any semiconductor-based structure having a semiconductor surface. Wafer and structure should be understood to include doped and undoped semiconductors, epitaxial semiconductor layers, if appropriate supported by a base support, and further semiconductor structures. For example, a layer of a first semiconductor material can be grown on a growth substrate of a second semiconductor material, for example a GaAs substrate, a GaN substrate or a Si substrate, or of an insulating material, for example on a sapphire substrate.

Depending on the intended use, the semiconductor can be based on a direct or an indirect semiconductor material. Examples of semiconductor materials particularly suitable for generating electromagnetic radiation comprise, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, and further semiconductor materials such as GaAs, AlGaAs, InGaAs, AlInGaAs, SiC, ZnSe, ZnO, Ga₂O₃, diamond, hexagonal BN and combinations of the materials mentioned. The stoichiometric ratio of the compound semiconductor materials can vary. Further examples of semiconductor materials can comprise silicon, silicon-germanium and germanium. In the context of the present description, the term “semiconductor” also includes organic semiconductor materials.

The term “substrate” generally comprises insulating, conductive or semiconductor substrates.

The term “vertical” as used in this description is intended to describe an orientation which is substantially perpendicular to the first surface of a substrate or semiconductor body. The vertical direction can correspond, for example, to a growth direction in the growth of layers.

The terms “lateral” and “horizontal” as used in this description are intended to describe an orientation or orientation which is substantially parallel to a first surface of a substrate or semiconductor body. This can be, for example, the surface of a wafer or of a chip (die).

The horizontal direction can lie, for example, in a plane perpendicular to a growth direction in the growth of layers.

In the context of this description, the term “electrically connected” means a low-resistance electrical connection between the connected elements. The electrically connected elements do not necessarily have to be directly connected to one another. Further elements can be arranged between electrically connected elements.

The term “electrically connected” also comprises tunnel contacts between the connected elements.

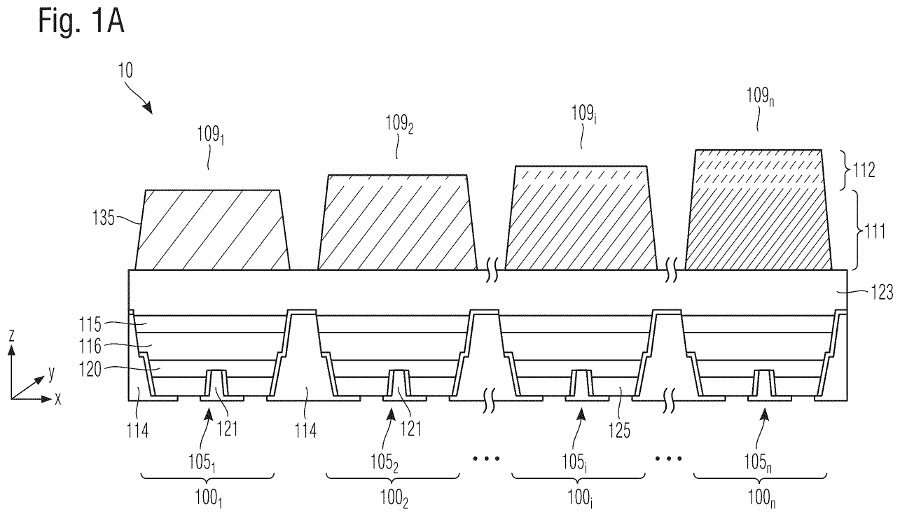

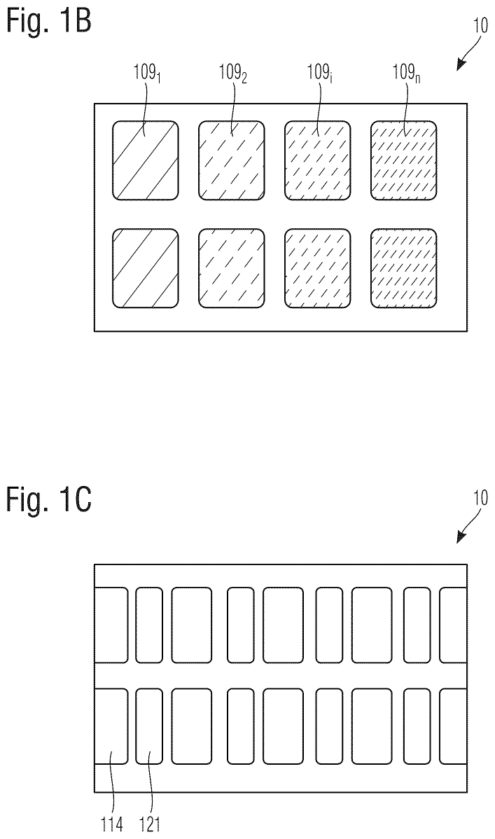

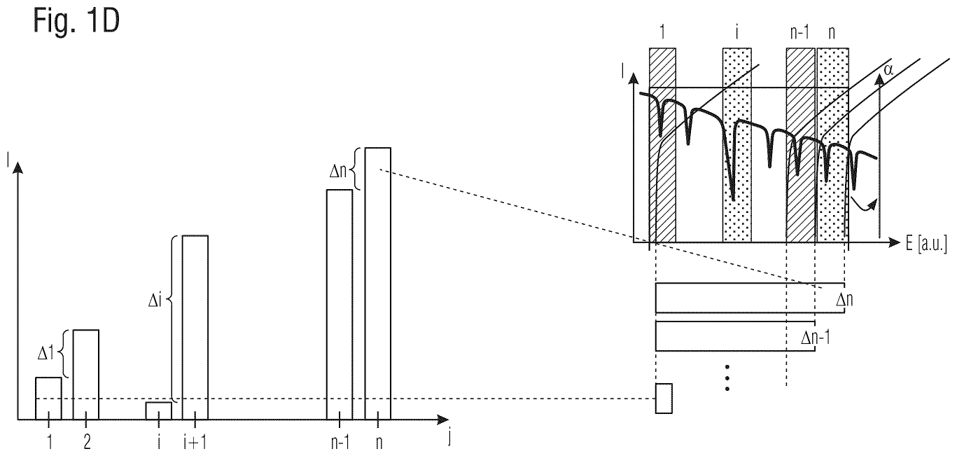

FIG. 1A shows a cross-sectional view of a sensor 10 according to embodiments. The sensor comprises an arrangement of sensor elements 100₁, 100₂, . . . 100ₙ. Each of the sensor elements 100ᵢ comprises an individually readable detector element 105ᵢ and a filter element 109i arranged above the detector element 105ᵢ. The filter element 109ᵢ comprises a first compound semiconductor material 135 having a composition ratio changing along a vertical direction. At least two filter elements 109ᵢ, 109ᵢ₊₁ have different layer thicknesses of the semiconductor material 135.

As illustrated in FIG. 1A, the individual detector elements 105ᵢ can comprise a semiconductor diode. For example, the semiconductor diode can be embodied as a PN or PIN diode. The detector element 105ᵢ can comprise, for example, a p-type semiconductor layer 115, an i-type semiconductor layer 116 and an n-type semiconductor layer 120, which are arranged one above the other. The i-type semiconductor layer 116 can be omitted. For example, a first intermediate layer 123 can be arranged between a surface of the p-type semiconductor layer 115 and the corresponding filter element 109ᵢ. The first intermediate layer 123 can comprise a plurality of layers. The first intermediate layer 123 can comprise suitable layers, for example buffer layers or other layers. Furthermore, a second intermediate layer 125 can be arranged adjacent to an exposed surface of the n-type semiconductor layer 120. The second intermediate layer 125 can comprise a plurality of layers. The second intermediate layer 125 can comprise suitable superlattice structures, for example for matching lattice constants or for lattice constant superphasing, buffer layers, stress-reducing layer sequences and others.

A p-type contact element 114 is electrically connected to the p-type semiconductor layer 115. An n-type contact element 121 is electrically connected to the n-type semiconductor layer 120. For example, the p-type contact element 114 and the n-type contact element 121 can be contactable from a rear side of the sensor 10. The individual detector elements 105ᵢ can be driven individually via the p-type contact element 114 and the n-type contact element 121, respectively. The detector elements 105ᵢ can each have an identical construction.

It goes without saying that the specified construction of the individual detector elements 105ᵢ is to be understood merely as an example and the detector elements 105ᵢ can be embodied in any other desired manner.

For example, the detector element 105ᵢ can be formed in a second compound semiconductor material, wherein at least one composition element of the second compound semiconductor material is a component of the first compound semiconductor material 135. Correspondingly, the semiconductor layers 115, 116, 120 can comprise, for example, the second compound semiconductor material.

However, according to further embodiments, the detector element 105ᵢ can also be formed in a semiconductor material different from the first compound semiconductor material 135. For example, the detector element 105ᵢ can be formed in silicon. Correspondingly, the semiconductor layers 115, 116, 120 can also contain silicon or consist of silicon.

In general, a second compound semiconductor material or semiconductor material of the detector elements 105ᵢ can be selected such that the electromagnetic radiation selectively transmitted through the filter elements 109ᵢ is detectable. The lower detection limit can be defined by the selection.

As illustrated in FIG. 1A, at least two of the filter elements 109ᵢ, 109ᵢ₊₁ have a different layer thickness along a vertical direction, for example the z-direction. For example, the filter elements 109ᵢ can comprise a region 111 having a constant composition ratio and a region 112 having a changing composition ratio, respectively.

Due to the changing composition ratio, the band gap and thus the electromagnetic radiation transmitted through the respective filter element 109ᵢ also varies. In particular, a band gap of the first compound semiconductor material 135 decreases with increasing distance from a surface of the associated detector element. For example, the composition ratio changes monotonically, i.e. the concentration of a component decreases monotonically to or monotonically along the vertical direction. As a result, the band gap of the first compound semiconductor material decreases monotonically with increasing distance from the surface of the associated detector element.

As a result, referring to FIG. 1A, the filter element 109₁ absorbs a comparatively small wavelength range compared to the filter element 109ₙ. A comparatively large wavelength range or energy range is transmitted and detected by the detector element 105₁. In addition, the filter element 109ₙ absorbs a comparatively large wavelength range. Correspondingly, only a small wavelength range or energy range is transmitted and detected by the detector element 105ₙ. The wavelength range transmitted by the filter element 109ₙ is the higher-wavelength range having lower energy with respect to the broad wavelength range transmitted by the filter element 109₁.

This will be explained in more detail with reference to FIG. 1D.

FIG. 1B shows a plan view of a top side of the sensor 10. As can be seen, the individual filter elements 109ᵢ can be arranged in rows and columns, respectively. In this case, for example, within a column, the layer thickness of the first compound semiconductor layer 135 can be identical in each case and increase or decrease along a row direction.

FIG. 1C shows a view of a bottom side of the sensor. As can be seen, a plurality of p-type contact elements 114 and n-type contact elements 121 are arranged in rows and columns. Individual sensor elements 100; can be addressed in a targeted manner by contacting and driving the corresponding p-type contact elements 114 and n-type contact elements 121.

As has been shown in FIG. 1A, the layer thickness of the first compound semiconductor layer 135 varies among the filter elements 1091. Examples of suitable compound semiconductor materials comprise AlₓGa₁₋ₓAs. For example, x can vary in a range from 0.4 to 0.05. For example, x can decrease in the vertical direction, such that regions in the vicinity of a surface of the detector elements have a higher Al content than regions having a greater distance from the surface of the detector elements. AlₓGa₁₋ₓAs has a lattice constant that is largely independent of the composition ratio. Correspondingly, AlₓGa₁₋ₓAs having a different composition ratio can be formed in a largely stress-free manner. According to embodiments, the second compound semiconductor material can contain GaAs. Correspondingly, the detector elements 105ᵢ can detect electromagnetic radiation having an energy greater than 1.4 eV.

Due to the fact that, as shown in FIG. 1A, the detector element 109ₙ covers a large band gap range, only electromagnetic radiation having an energy greater than the largest band gap of the first compound semiconductor material 135 is transmitted through the filter element 109ₙ and then detected by the detector element 105ₙ. Conversely, a large wavelength range is transmitted by the filter element 109₁ and detected by the detector element 105₁. An intermediate wavelength range is transmitted by an intermediate filter element 109ᵢ and detected by the detector element 105ᵢ.

FIG. 1D shows examples of measured intensities of electromagnetic radiation at the individual detector elements 105₁, 105₂, 105ᵢ, 105ᵢ₊₁, . . . 105ₙ₋₁, 105ₙ. An example of an intensity distribution to be resolved is illustrated at the top right in the insert image, together with absorption coefficients for different composition ratios of the first compound semiconductor material.

The minimum of the detected intensity at the detector element i corresponds, for example, to the intensity minimum of the radiation to be detected. As can be seen in FIG. 1D, the intensity in the region i results, for example, from a direct comparison of the intensity signals of adjacent detector elements 105ᵢ₊₁, 105ᵢ. More precisely, a conclusion can be drawn on the intensity contribution of the spectrum in the corresponding interval by the comparison of the intensities in adjacent detector elements. By pixel-fine ablation, it can be set which energies are still filtered out or absorbed by the pixel layer and do not impinge on the associated detector element 105ᵢ.

The filter material can comprise any desired compound semiconductor materials whose band gap can be varied by changing the composition ratio. Further examples of suitable material systems comprise InₓAlyGa_{100-x-y}N, InₓGa₁₀₀₋ₓAs_{y} P_{100-y} or InₓGA₁₀₀₋ₓAs_{y} SB_{100-y}. For example, a material system can be selected in which the lattice constant changes only slightly with a change in the composition ratio.

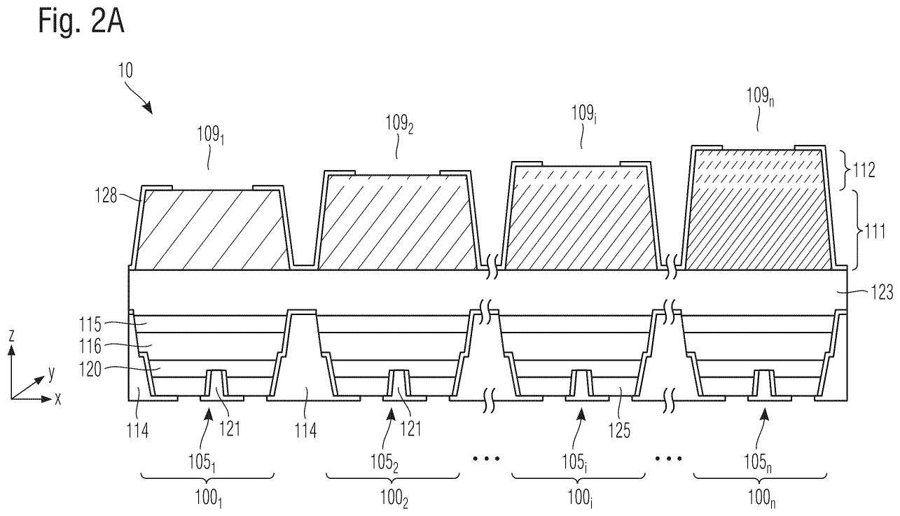

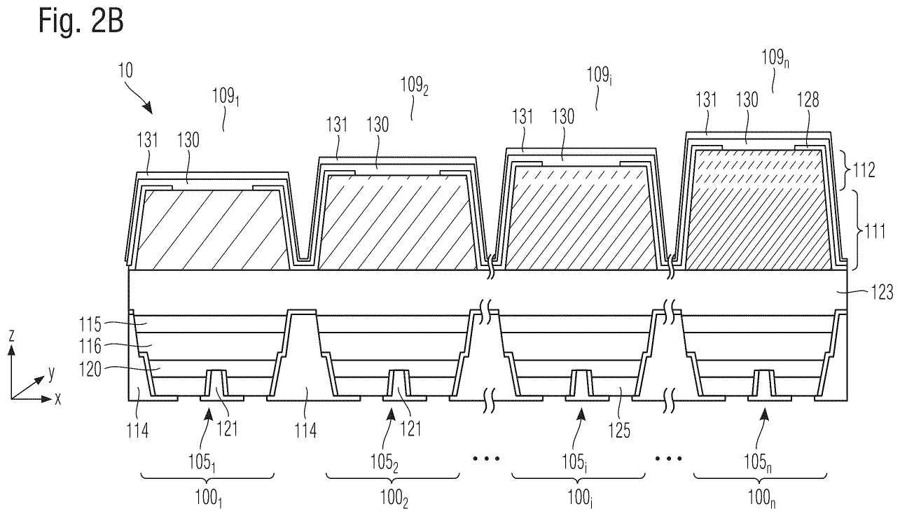

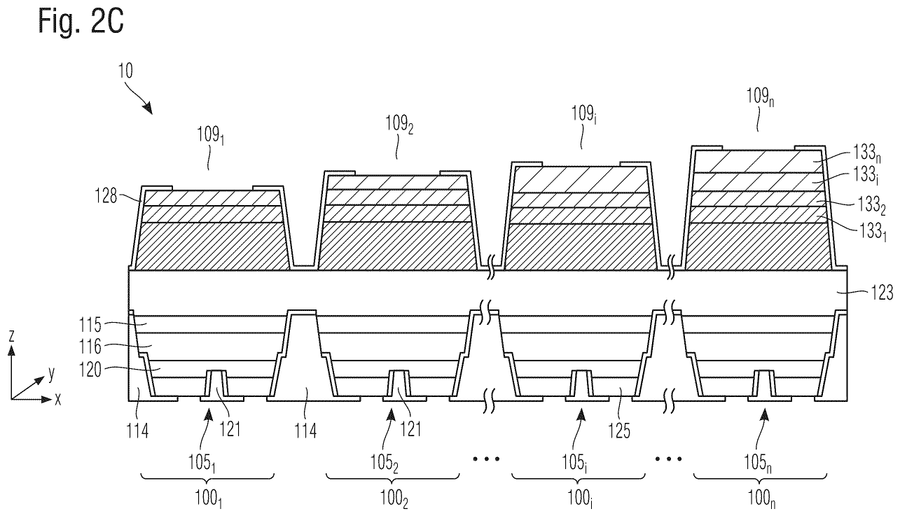

FIG. 2A shows a cross-sectional view of a sensor 10 according to further embodiments. The sensor 10 has identical or similar components as the sensor shown in FIG. 1A. In addition, a cover element or a mask layer 128 is provided at the edge of each filter element 109ᵢ. The cover element 128 covers the side flanks. The cover element 128 can further cover a part of the surface in the edge region of each filter element 109ᵢ. The cover element 128 can comprise, for example, a non-translucent material or a material which is not transparent to the incident electromagnetic radiation. Specific examples comprise, for example, any desired metals or else polymers, for example silicone, which can contain suitable additives, for example carbon black particles, if appropriate with a passivating, for example insulating, intermediate layer. Crosstalk between adjacent sensor elements 100i can be reduced by the cover element 128.

FIG. 2B shows a cross-sectional view of a sensor according to further embodiments. In addition to elements which are shown in FIG. 1A or 2A, a filter layer 131 is arranged above the filter elements 109i. For example, the filter layer 131 can comprise a bandpass filter which can filter out the non-relevant proportion of the spectrum. As a result, the signal-to-noise ratio can be increased. For example, the filter layer can be realized as a dielectric mirror or comprise another semiconductor material, for example having a greater band gap, which can be greater than 3 eV, for example. The filter layer 131 can be identical for all sensor elements 100₁, 100₂, . . . 100ₙ.

Furthermore, a passivation layer can be arranged above the filter elements 109ᵢ. The passivation layer 130 can comprise, for example, SiO₂, SiN or another material which is transparent to the incident electromagnetic radiation. Oxidative stress can be reduced by the passivation layer, for example. According to further embodiments, impurities, lattice voids or lattice defects can be incorporated in the passivation layer or first compound semiconductor material layer. For example, a concentration of lattice voids or lattice defects in an order of magnitude of 10⁻⁸ to 10⁻⁹ can be contained. According to further embodiments, a semiconductor material having an indirect band gap, for example silicon, can also be incorporated. A non-radiative recombination of the charge carriers generated in the filter element 109ᵢ is facilitated by the impurities, lattice defects or the semiconductor material having an indirect band gap. The passivation layer can have a layer thickness of greater than 50 nm, for example. For example, the layer thickness can be less than approximately 3 μm. For example, the layer thickness can be a few 100 nm.

According to embodiments, the composition of the first compound semiconductor material 135 can change continuously. However, according to further embodiments, the composition can also change stepwise. For example, each of the filter elements 109ᵢ can comprise a plurality of partial layers 133₁, . . . 133ₙ, which have a different composition ratio, respectively. For example, the composition ratio of partial layer to partial layer can change monotonically in a vertical direction, i.e. the proportion of a component can increase but not decrease exclusively from partial layer to partial layer. In this embodiment, the composition ratio is constant within a partial layer. As a result, for example, the lattice constant of the first compound semiconductor material can also be constant. The individual regions having a virtually constant lattice constant can thus also be covered by a suitable selection of corresponding material regions, for example four to five material regions. As a result, a stress-free and thus arbitrarily thick layer growth is possible.

As will be explained below, the respectively different layer thickness of the first compound semiconductor layer 135 is achieved, for example, by etching back. In this case, an etching method can be selected in which the etching rate is highly dependent on the material composition.

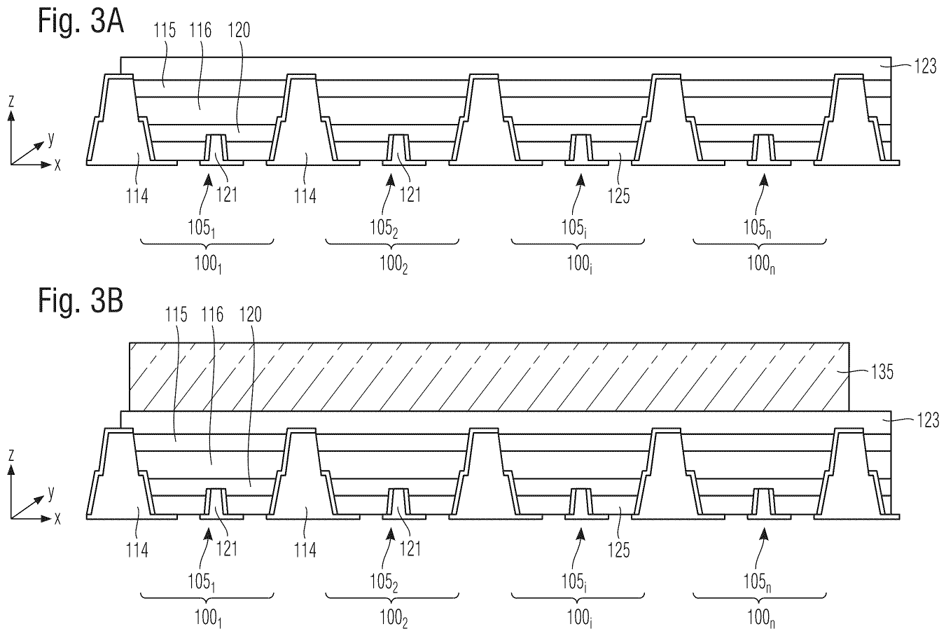

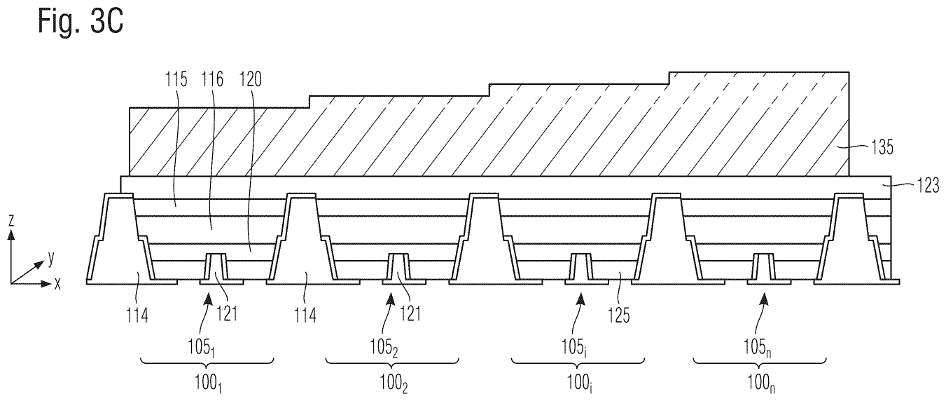

FIGS. 3A to 3C illustrate a method for manufacturing the sensor according to embodiments. For example, first the detector elements 105i can be formed in a suitable material system. FIG. 3A shows a cross-sectional view of the completed detector elements 105ᵢ. Then, a first compound semiconductor material layer 135 having a composition ratio changing in the vertical direction is applied. As has been explained with reference to FIG. 2C, the composition of the first compound semiconductor layer 135 can change continuously or else stepwise.

The composition ratio changes such that the band gap decreases with increasing distance from a surface of the detector elements 105ᵢ. For example, the first compound semiconductor material can be selected such that the lattice constant remains constant as a result of the change in the composition ratio. FIG. 3B shows an example of a resulting workpiece.

Subsequently, an etching method is carried out, wherein different regions of the first compound semiconductor material layer 135 are etched to different depths. For example, the stepped profile shown in FIG. 3C can result. Subsequently, for example, the individual filter elements 109i can be separated from one another by etching, resulting in the structure shown in FIG. 1A or 2A.

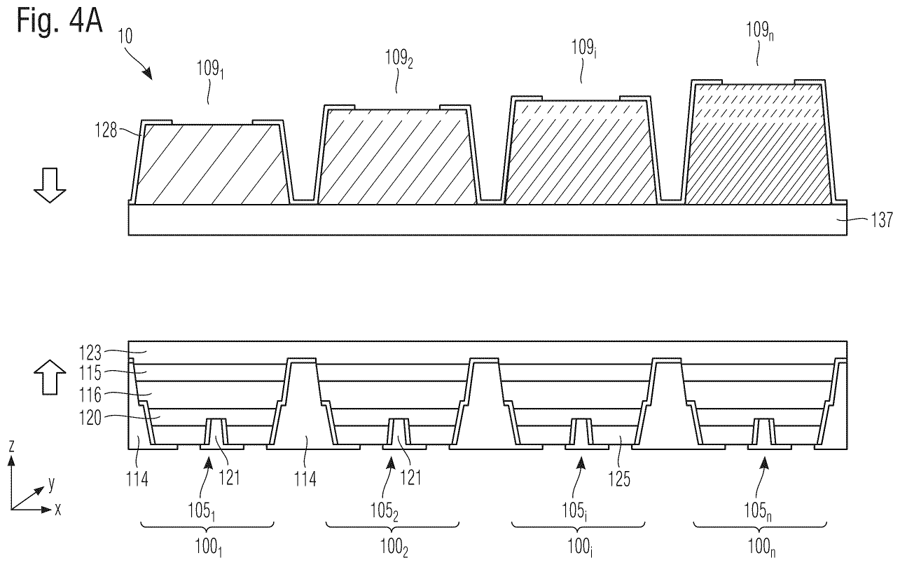

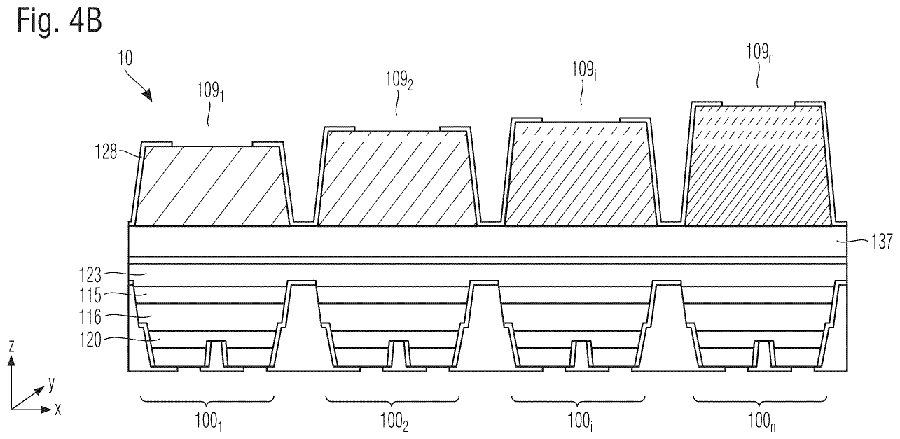

According to further embodiments, as illustrated in FIG. 4A, the individual filter elements 109ᵢ can also be formed on a separate carrier 137. For example, this can be accomplished by forming a first compound semiconductor layer 135 over the carrier 137 and then etching back. Subsequently, as further illustrated in FIG. 4A, the carrier 137 comprising the filter elements 109ᵢ can be connected to an arrangement of detector elements 105ᵢ.

As a result, the arrangement shown in FIG. 4B can be obtained. For example, this procedure can be favorable if different material systems are used for the filter elements 109ᵢ and the detector elements 105ᵢ.

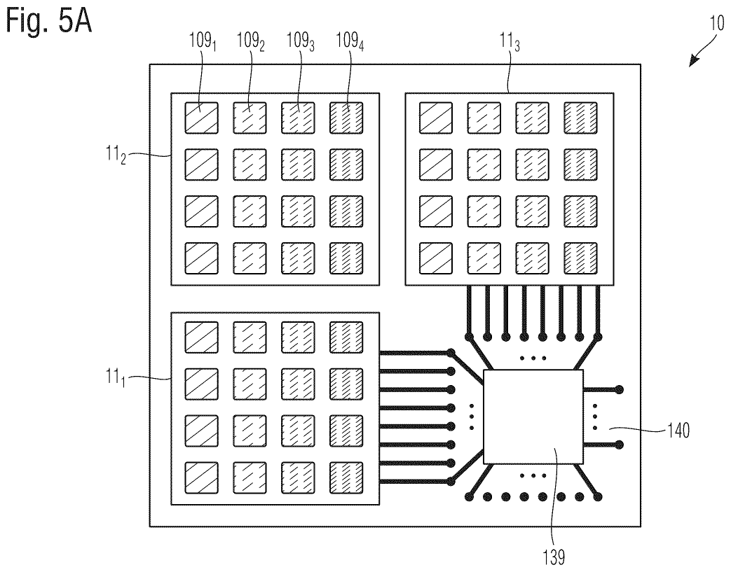

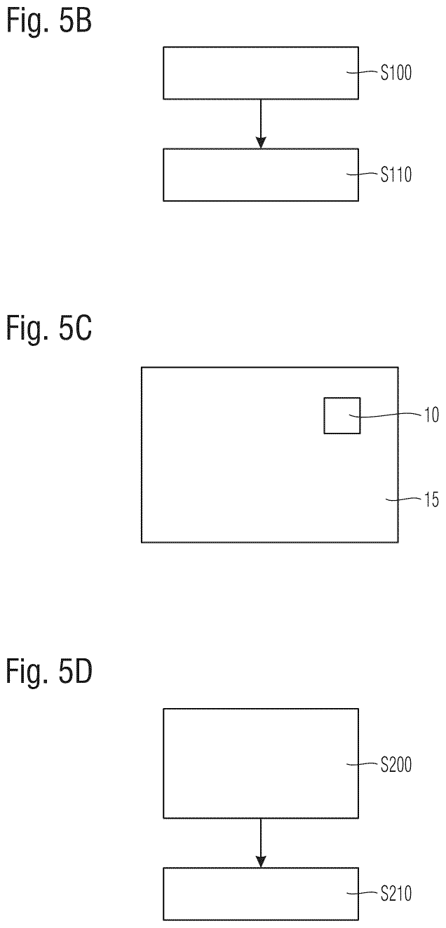

FIG. 5A shows an example of a sensor 10 comprising different sensor areas 11₁, 11₂, 11₃. The sensor areas each contain arrangements of sensor elements in which the individual filters are based on different material systems. A large energy range in a range from <0.5 eV to >3 eV, i.e. the NIR to N-UV range, can be covered by a skillful combination of different material systems. As is further shown in FIG. 5A, the filter elements can have a different layer thickness within each individual sensor area 11₁, 11₂, 11₃. FIG. 5A further illustrates a control logic 139 for driving the respective detector elements 105ᵢ and for reading out.

It is possible to tune the absorption properties of a sensor in a broad range by the special construction of the individual filter elements. In particular, if the composition ratio changes continuously within the first compound semiconductor layer, the absorption or detection edges can be tuned continuously. As a result, a broad variability results in the tuning of the detection wavelength ranges to be separated from one another. Due to the construction of the sensor the collected light is used more efficiently than in conventional sensors. In particular, the proportion of the spectrum which is not to be detected by the associated detector region is filtered out by the filter region, respectively. A comparison of detected intensities allows a conclusion to be drawn on the spectrum proportion. Correspondingly, a higher proportion of the incident electromagnetic radiation is fed to the sensor and thus not filtered.

FIG. 5B summarizes a method for manufacturing a sensor comprising an arrangement of sensor elements, which comprise an individually readable detector element and a filter element arranged above an associated detector element, respectively. The method comprises forming (S100) a plurality of filter elements, which contain a first compound semiconductor material having a composition ratio changing along a vertical direction, respectively, and
removing (S110) a part of the first compound semiconductor material of at least one filter element, so that layer thicknesses of the first compound semiconductor material that are different from one another are achieved over at least two detector elements.

FIG. 5C shows an electronic device 15 comprising the sensor 10 as described above. The electronic device 15 can be selected from an exploration satellite, for example, which is suitable for carrying out a surface determination (soil, vegetation, water, etc.), for exploring natural resources, for making meteorological predictions. Further examples of the electronic device 15 comprise an analysis device, for example for biomedical applications, for example for investigating (skin) burns, documents, works of art or for controlling the growth of plants in the horticulture field or generally in the military field.

FIG. 5D summarizes a method for operating a sensor as described above. The method comprises reading out (S200) detector signals of at least two sensor elements, which have different layer thicknesses of the filter element, respectively, and determining (S210) a spectral signal from the difference of the detector signals.

Although specific embodiments have been illustrated and described herein, persons skilled in the art will recognize that the specific embodiments shown and described can be replaced by a multiplicity of alternative and/or equivalent embodiments without departing from the scope of protection of the invention. The application is intended to cover any adaptations or variations of the specific embodiments discussed herein. Therefore, the invention is restricted only by the claims and the equivalents thereof.

1.-18. (canceled)

19. A sensor comprising:
individually readable detector elements; and
filter elements arranged above the detector elements, respectively,
wherein each filter element comprises a first compound semiconductor material having a composition ratio changing along a vertical direction,
wherein the first compound semiconductor material is a III-V semiconductor material, which comprises elements of group III and at least one element of group V,
wherein a proportion of the elements of group III changes along the vertical direction and a proportion of the at least one element of group V remains greater than zero, and
wherein at least two filter elements have layer thicknesses of the first compound semiconductor material that are different from one another.

20. The sensor according to claim 19, further comprising a cover element arranged between two neighboring filter elements.

21. The sensor according to claim 20, wherein the cover element covers a part of a surface of the filter elements.

22. The sensor according to claim 19, further comprising a filter layer over the filter elements.

23. The sensor according to claim 19, wherein the composition ratio changes continuously.

24. The sensor according to claim 19, wherein the composition ratio changes stepwise.

25. The sensor according to claim 19, wherein each detector element comprises a second compound semiconductor material, and wherein at least one composition element of the second compound semiconductor material is a component of the first compound semiconductor material.

26. The sensor according to claim 19, wherein each detector element comprises a semiconductor material different from the first compound semiconductor material.

27. The sensor according to claim 19, wherein at least two detector elements are identical.

28. The sensor according to claim 19, wherein a band gap of the first compound semiconductor material decreases with increasing distance from a surface of the associated detector element.

29. The sensor according to claim 19, wherein the first compound semiconductor material layer additionally comprises impurities, lattice voids, lattice defects or a semiconductor material having an indirect band gap.

30. The sensor according to claim 19, further comprising a transparent, insulating passivation layer arranged over the first compound semiconductor material layer, wherein the passivation layer comprises impurities, lattice voids, lattice defects or a semiconductor material having an indirect band gap.

31. A method for manufacturing a sensor comprising individually readable detector elements and filter elements arranged over associated detector elements, respectively, the method comprising:
forming a plurality of filter elements, which comprise a first compound semiconductor material having a composition ratio changing along a vertical direction, respectively, wherein the first compound semiconductor material is a III-V semiconductor material, which comprises elements of group III and at least one element of group V, and wherein a proportion of the elements of group III changes along the vertical direction and a proportion of the at least one element of group V remains greater than zero; and
removing a part of the first compound semiconductor material of at least one filter element so that layer thicknesses of the first compound semiconductor material that are different from one another are achieved over at least two detector elements.

32. The method according to claim 31, wherein forming the plurality of filter elements comprises:
applying the first compound semiconductor material, and
removing a part of the first compound semiconductor material after applying the first compound semiconductor material.

33. The method according to claim 31, wherein the filter elements are applied over the detector elements after removing the part of the first compound semiconductor material.

34. A method for operating a sensor comprising individually readable detector elements and filter elements arranged over the detector elements, respectively, wherein each filter element comprises a first compound semiconductor material having a composition ratio changing along a vertical direction, wherein the first compound semiconductor material is a III-V semiconductor material, which comprise elements of group III and at least one element of group V, wherein a proportion of the elements of group III changes along the vertical direction and a proportion of the at least one element of group V remains greater than zero, and wherein at least two filter elements have layer thicknesses of the first compound semiconductor material that are different from one another, the method comprising:
reading out detector signals of the at least two filter elements having different layer thicknesses; and
determining a spectral signal from the difference of the detector signals.
